(19) United States
(12) Patent Application Publication
(10) Pub. No.: US 2002/0075054 A1
(43) Pub. Date: Jun. 20, 2002

(54) Read gain offset trim without feedback loop

(76) Inventor: Hiroyuki Mukai, Kanagawa-Ken (JP)

Correspondence Address: TEXAS INSTRUMENTS INCORPORATED, P O BOX 655474, M/S 3999, DALLAS, TX, 75265

(21) Appl. No.: 09/992,905

(22) Filed: Nov. 14, 2001

Related U.S. Application Data
(60) Provisional application No. 60/254,284, filed on Dec. 7, 2000.

(51) Int. Cl. H03L 5/00

(52) U.S. Cl. 327/307

(57) ABSTRACT

A trim circuit to trim a differential signal includes an input circuit to input an input differential signal to be trimmed and a resistive circuit to trim the input differential signal to obtain a trimmed differential output signal

### FIELD OF THE INVENTION

The present invention relates to the field of mass storage device and more particularly to the field of pre-amplifiers.

### BACKGROUND OF THE INVENTION

Hard disk drives include a stack of magnetically coded platters that are used for storing information. The magnetically coded platters are mounted together in a stacked position through a spindle which can be referred to as platter stack. The platter stack is rotated by a motor that is sometimes referred to as spindle motor or a servo motor. A space is provided between each platter to allow a read/write head or slider to be positioned on each side of the platter so that information may be stored and retrieved. Information is stored on each side of the platter and generally organized into sectors, tracks, zones and cylinders. Each of the read/write heads or sliders are mounted to one end of a dedicated suspension arm so that each of the read/write heads may be positioned as desired. The opposite end of each of the suspension arms are coupled together at a voice coil motor to form one unit or similarly that is positional by a voice coil motor. Each of the suspension arms are provided in a fixed position relative to each other. The voice coil motor positions all the suspension arms so that the active read/write head is properly positioned for reading or writing information. The read/write head or slider may be moved from at least an inner diameter to an outer diameter where data is stored and this distance may be referred to as a data stroke.

Hard disk drives include a variety of electronic circuitry for processing data and for controlling its overall operation. The electronic circuit may include a preamplifier, a read channel, a read only memory (ROM), a random access memory (RAM) and a variety of disk control circuitry to control the operation of the hard disk drive and to properly interface the hard disk drive to a system bus. The preamplifier may include a read preamplifier and a write preamplifier that is also referred to as a write driver. The preamplifier may be implemented in a single integrated circuit or a separate integrated circuit such as a read preamplifier and write preamplifier or write driver. The disk control circuitry generally includes a separate microprocessor for executing instructions stored in memory to control the operation and interface of the hard disk drive. The hard disk drive performs write to read and several operations when storing and retrieving data. Generally, a write operation includes receiving data from a system bus and storing data in the RAM. The microprocessor schedules a series of events to allow the information to be transferred from the RAM to platters through the write channel. Before the information is transferred, the read/write heads are positioned on an appropriate track and an appropriate sector of the track is located. The data from the RAM is then communicated to the write channel as a digital write signal. The write channel processes the digital write signal and generates an analog write signal. In doing this, the write channel may encode the data so that the data can be more reliably retrieved later. The digital write signal may then be provided as an appropriate read/write head after first being amplified by the preamplifier.

In a read operation, the appropriate sector to be read is located, and data has been previously written to the platter is read. The appropriate read/write head senses the changes to the magnetic flux and generates a corresponding analog read signal. The analog read signal is provided back to the electronic circuitry where the preamplifier amplifies the analog read signal. The amplified analog read signal is then provided to the read channel where the read channel conditions the signals and detects “zeros” and “ones” from the signal to generate the digital read signal. The read channel may condition the signal by amplifying the signal to an appropriate level using automated gain control (AGC) techniques. The read channel may then filter the signal to eliminate unwanted high frequency noise, equalize the signal, detect “zeros” and “ones” from the signal and format the digital read signal. The digital read signal is then transferred from the read channel to be stored in RAM. The microprocessor may then communicate to a host that the data is ready to be transferred.

The read channel may be implemented using any of the variety of known or available read channels. For example, the read channel may be implemented as a peak detector read channel or a more advanced type of read channel utilizing discreet time signal processing. The peak detection level read channel includes level detecting the amplified analog read signal and determines if the wave form level is above a threshold level during a sampling window. The discreet time level signal processing type read channel synchronously samples the amplified analog read signal using a data recovery clock. The sample is then processed through a series of mathematical manipulations using data processing theory to generate a digital read signal. There are several types of discreet time signal processing read channels such as partial response, maximum likelihood (PRML) channel and extended PRML channel and enhanced extended PRML channel, a fixed delayed tree search and a decision feedback equalization channel. As disk platters are moving, the read/write's head must align or stay on a particular track. This is accomplished by the servo operation through the use of a servo controller provided in a servo control loop. In a servo operation, a servo wedge is read from the track that generally includes track identification information and track misregistration information. The track misregistration information may also be referred to as position error information. The position error information may be provided to a servo bus that may be used during both read and write operations to ensure that the read and write heads are properly aligned on a track. As a result of receiving the position error information, the servo controller generates a corresponding control signal to position the read/write heads by positioning the voice coil motor. The track identification information is used during read and write operations so that a track may be properly identified.

Typically, in hard disk drive technology, a differential signal is used when reading data from the disk. The use of this differential signal and associated electronic component creates offsets in the differential signal because of differences in the component and the resulting effects that these differences in the components cause on the differential signal. In previous offset circuits, a feedback circuit has been proposed, but such a feedback circuit introduces a frequency response which is undesirable.

### SUMMARY OF THE INVENTION

This invention relates in general to the field of mass storage devices and more particularly to an offset compensation circuit.

The present invention provides a circuit to bias either the voltage V_{OUTX} or V_{ACTY} when either one of these output voltages are subject to offset. The present invention uses a static circuit which is a non-feedback circuit and consequently does not introduce a frequency response. The present invention adds current to a current path which increases or decreases the DC voltage drop at the output. The present invention reduces offset due to capacitance between the read and write elements of the head.

### BRIEF DESCRIPTION OF THE DRAWINGS

FIG. 1 illustrates a circuit of the present invention;

FIG. 2 illustrates a detailed circuit of the present invention;

FIG. 3 illustrates a top view of a system of the present invention; and

FIG. 4 illustrates a side view of the system of the present invention.

### DETAILED DESCRIPTION OF THE PRESENT INVENTION

The following invention is described with reference to figures in which similar or the same numbers represent the same or similar elements. While the invention is described in terms for achieving the invention's objectives, it can be appreciated by those skilled in the art that variations may be accomplished in view of these teachings without deviation from the spirit or scope of the invention.

FIGS. 3 and 4 show a side and top view, respectively, of the disk drive system designated by the general reference 1100 within an enclosure 1110. The disk drive system 1100 includes a plurality of stacked magnetic recording disks 1112 mounted to a spindle 1114. The disks 1112 may be conventional particulate or thin film recording disk or, in other embodiments, they may be liquid-bearing disks. The spindle 1114 is attached to a spindle motor 1116 which rotates the spindle 1114 and disks 1112. A chassis 1120 is connected to the enclosure 1110, providing stable mechanical support for the disk drive system. The spindle motor 116 and the actuator shaft 1130 are attached to the chassis 1120. A hub assembly 1132 rotates about the actuator shaft 1130 and supports a plurality of actuator arms 1134. The stack of actuator arms 1134 is sometimes referred to as a “comb.” A rotary voice coil motor 1140 is attached to chassis 1120 and to a rear portion of the actuator arms 1134.

A plurality of head suspension assemblies 1150 are attached to the actuator arms 1134. A plurality of inductive transducer heads 1152 are attached respectively to the suspension assemblies 1150, each head 1152 including at least one inductive write element. In addition thereto, each head 1152 may also include an inductive read element or a MR (magneto-resistive) read element. The heads 1152 are positioned proximate to the disks 112 by the suspension assemblies 1150 so that during operation, the heads are in electromagnetic communication with the disks 1112. The rotary voice coil motor 1140 rotates the actuator arms 1134 about the actuator shaft 1130 in order to move the head suspension assemblies 1150 to the desired radial position on disks 1112.

A controller unit 1160 provides overall control to the disk drive system 1100, including rotation control of the disks 1112 and position control of the heads 1152. The controller unit 1160 typically includes (not shown) a central processing unit (CPU), a memory unit and other digital circuitry, although it should be apparent that these aspects could also be enabled as hardware logic by one skilled in the computer arts. Controller unit 1160 is connected to the actuator control/drive unit 1166 which is in turn connected to the rotary voice coil motor 1140. A host system 1180, typically a computer system or personal computer (PC), is connected to the controller unit 1160. The host system 1180 may send digital data to the controller unit 1160 to be stored on the disks, or it may request that digital data at a specified location be read from the disks 1112 and sent back to the host system 1180. A read/write channel 1190 is coupled to receive and condition read and write signals generated by the controller unit 1160 and communicate them to an arm electronics (AE) unit shown generally at 1192 through a cut-away portion of the voice coil motor 1140. The AE unit 1192 includes a printed circuit board 1193, or a flexible carrier, mounted on the actuator arms 1134 or in close proximity thereto, and an AE module 1194 mounted on the printed circuit board 1193 or carrier that comprises circuitry preferably implemented in an integrated circuit (IC) chip including read drivers, write drivers, and associated control circuitry. The offset circuit of the present invention is located in the AE module 1194. The AE module 1194 is coupled via connections in the printed circuit board to the read/write channel 1190 and also to each read head and each write head in the plurality of heads 1152.

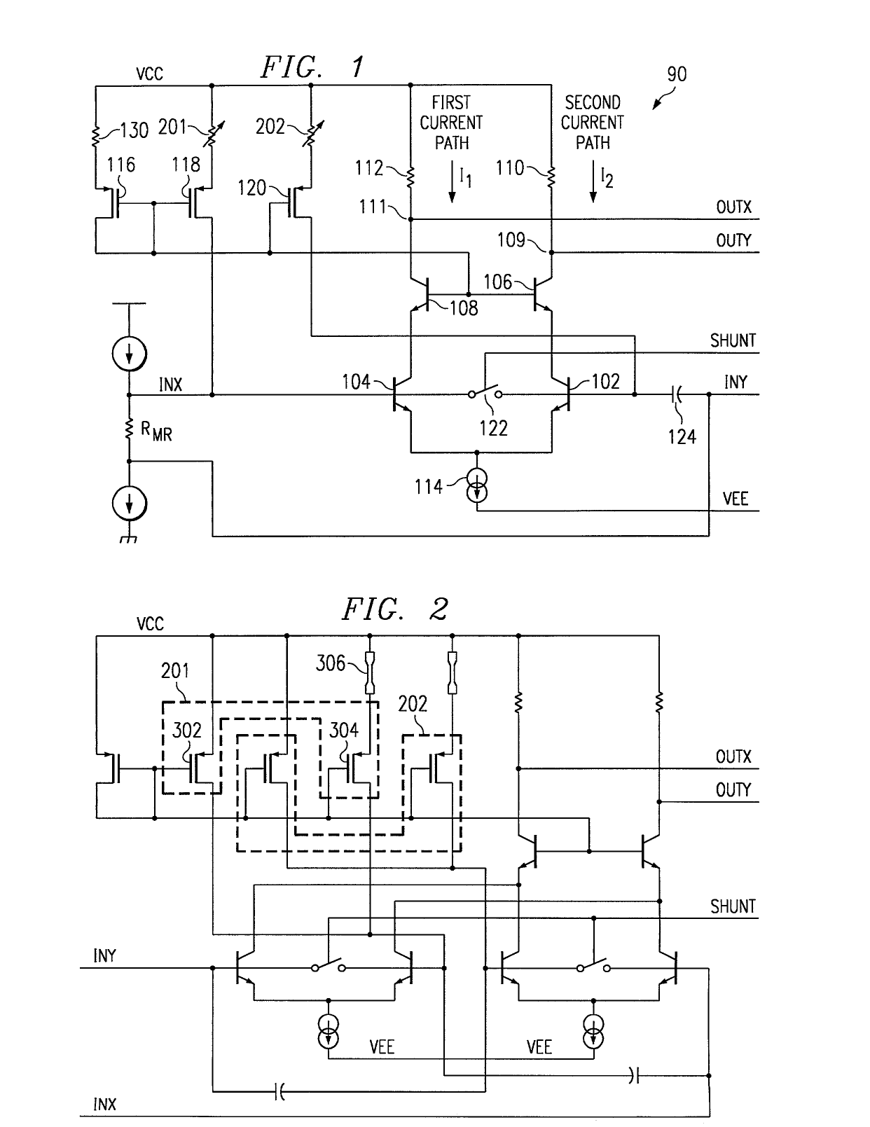

Turning to FIG. 1, which illustrates the offset circuit 90 of the present invention, a current generator 114 is connected to voltage V_{EE} to which the other end of current generator 114 is connected to the emitter of transistor 104 and the emitter of transistor 102. Transistors 109 and 104 receive the differential input signal I_{NX} and I_{NY} respectively, to be offset adjusted. The collector of transistor 104 is connected to the emitter of transistor 108 and the collector of transistor 108 is connected to resistor 112. The other end of resistor 112 is connected to V_{CC}. The resistor 112, the transistor 108 and the transistor 104 form a first current path. Additionally, the collector of transistor 102 is connected to the emitter of transistor 106 and the collector of transistor 106 is connected to resistor 110. The other end of resistor 110 is connected to V_{CC}. The resistor 110, transistor 106 and transistor 102 form a second current path. The output voltage V_{OUTX} at terminal 14 is connected between the collector of transistor 108 and resistor 112. The output of voltage V_{OUTY} at terminal 109 is connected between the collector of 106 and transistor 110. The base of transistor 108 is connected to the base of transistor 106 at to resistor R_{MR} (head) and the base of transistor 104 is connected to shunt circuit 122 and the base of 102 is connected to the other end of shunt circuit 122 and to capacitor 124. The drain of PFET 116 is connected to the base of transistors 108 and 106. The source of NFET 116 is connected to resistor 130, and the other end of resistor 130 is connected to voltage V_{CC}. The gate of PFET 116 is connected to the drain of PFET 116 and connected to the gate of PFET 118 and PFET 120. Thus, the PFET 116 forms a current mirror both with PFET 118 and PFET 120. The source of PFET 118 is connected to variable resistance 201 and the source of PFET 120 is connected to variable resistance 202. The other end of variable resistance 201 is connected to the voltage V_{CC} and the other end of variable resistance 202 is connected to V_{CC}.

Next, the operation of FIG. 1 is described.

In operation, the current I₁ that flows through the first current path I₁ and the current l₂ that flows through the second current path is determined by the base current of transistor 104 or transistor 102 depending on whether the first current path or the second current path is being considered. The transistors 104 and 102 operate such that each of these transistors is operating in the operating range. The current flowing to the bases of transistor 104 and transistor 102 is affected by the current flowing through the variable resistor 102 and variable resistor 102, respectively.

Taking transistor 104 and resistor 201 as representative, as the resistance of resistor 201 is decreased, the current through transistor 201 increases resulting in more current flowing to the base of transistor 104. Since the current flowing through the first current path, namely the current flowing through the collector to emitter of transistor 104 is related by the β, varying the resistance of resistor 201 varies the current I₁ in the first current path. The more current in the first current path lowers voltage VOUTX because the I_{R} drop across resistor 112 increases. The voltage VOUTX is increasingly lowered as the current I₁ is increased.

Thus, circuit 90 trims the differential signal, namely voltage V_{OUTX} and V_{OUTY}.

Thus, the operating point of transistor 104 is determined by variable transistor 201. Shunt switch 122 connects the bases of transistors 104 and 102 together to force the currents in the first current path and the second current path to be the same. The voltage V_{OUTX} is determined by the voltage drop across resistor 112.

FIG. 2 illustrates the details of variable resistor 201 and the details on variable resistor 202. More specifically, variable resistor 201 includes FET 304 and fuse 306 in series. By blowing fuse 306, the resistance of FET 304 is eliminated from variable resistor 201. The variable resistor 202 operates in a similar fashion.

1. A trim circuit to trim a differential signal;
an input circuit to input an input differential signal to be trimmed; and
a resistive circuit to trim said input differential signal to obtain a trimmed differential output signal.

2. A trim circuit to trim a differential signal as in claim 1, wherein said input circuit is a first and second transistor.

3. A trim circuit to trim a differential signal as in claim 2, wherein said resistive circuit adjusts the operating point of said first transistor and said second transistor.

4. A trim circuit to trim a differential signal as in claim 1, wherein said resistor circuit includes a fused resistor.
